(19) United States
(12) Patent Application Publication
(10) Pub. No.: US 2006/0001163 A1
(43) Pub. Date: Jan. 5, 2006

(54) Groundless flex circuit cable interconnect

(76) Inventors: Mohammad Kolbehdari, Hillsboro, OR (US); Edward A. Burton, Hillsboro, OR (US)

Correspondence Address: SCHWABE, WILLIAMSON & WYATT, P.C.;PACWEST CENTER, SUITE 1900, 1211 SW FIFTH AVENUE, PORTLAND, OR, 97204, US

(21) Appl. No.: 10/883,528

(22) Filed: Jun. 30, 2004

(51) Int. Cl. H01L 23/48; H01L 21/4763

(52) U.S. Cl. 257/758; 257/685; 438/622

(57) ABSTRACT

Embodiments of the present invention include an apparatus, method, and/or system for using a groundless flex circuit cable to interconnect semiconductor packages.

### FIELD

The present invention relates to integrated circuits, and more particularly, but not limited to, providing connections to integrated circuits through a groundless flex circuit cable.

### BACKGROUND

Data transfer bit rates of processors are progressively increasing. In order to take advantage of these high rates, computer systems attempt to transmit signals along their buses and between system components at comparable rates.

Today's high data transfer rates of about 5-10 Gb/s and beyond are challenging conventional signal routing solutions, which may be constrained to a few Gb/s. Conventional signal routing solutions route signals between semiconductor packages through the printed circuit board. Signals transmitted from a driver package to a receiver package through the printed circuit board may experience a number of issues that may compromise the signal integrity. Some of these issues could include discontinuities and impedance mismatches between the packages and the printed circuit board, as well as dielectric and conductor losses through the signal path in the printed circuit board. These issues may unnecessarily constrain both the distance and the rates that the signals may be reliably transmitted.

### BRIEF DESCRIPTION OF THE DRAWINGS

The present invention will be described by way of exemplary embodiments, but not limitations, illustrated in the accompanying drawings in which like references denote similar elements, and in which:

FIG. 1 illustrates a perspective view of a semiconductor package coupled to a flex circuit cable, in accordance with an embodiment of this invention;

FIG. 2 illustrates a cross-sectional view of a flexible interconnect bus of the flex circuit cable, in accordance with an embodiment of this invention;

FIG. 3 illustrates a transmitting signal trace pair coupling two semiconductor packages, in accordance with an embodiment of the present invention;

FIGS. 4a-4d illustrate various coupling embodiments using a flex circuit cable;

FIG. 5 illustrates a backplane arrangement utilizing flex circuit cables, in accordance with an embodiment of the present invention; and

FIG. 6 depicts a block diagram of a system including a flex circuit cable, in accordance with an embodiment of the present invention.

### DETAILED DESCRIPTION

A method, apparatus, and system for using a groundless flex circuit cable to interconnect semiconductor packages is disclosed herein. In the following detailed description, reference is made to the accompanying drawings that form a part hereof wherein like numerals designate like parts throughout. The drawings may show, by way of illustration, specific embodiments in which the invention may be practiced; however, it is to be understood that other embodiments may be utilized and structural or logical changes may be made without departing from the scope of the embodiments of the present invention. It should also be noted that directions and references (e.g., top, bottom, etc.) may be used to facilitate the discussion of the drawings but are not intended to restrict the application of the embodiments of this invention. Therefore, the following detailed description is not to be taken in a limiting sense and the scope of the embodiments of the present invention are defined by the appended claims and their equivalents.

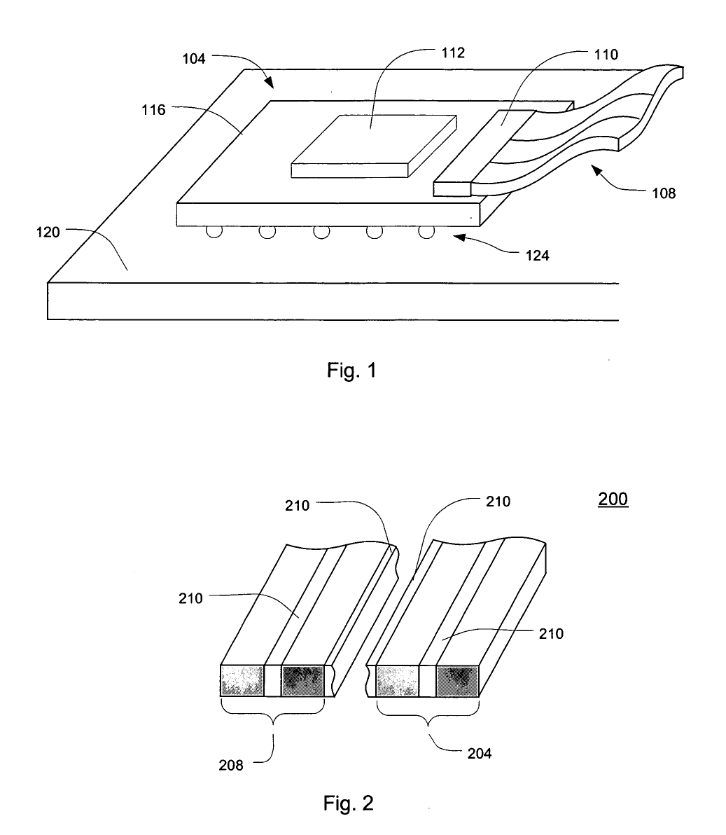

FIG. 1 illustrates a perspective view of a semiconductor package 104 coupled to a flex circuit cable 108, in accordance with an embodiment of this invention. In this embodiment the semiconductor package 104 may include a die 112 electrically and mechanically coupled to a package substrate 116. The flex circuit cable 108 may also be electrically and mechanically coupled to the package substrate 116 so that differential signals may be routed between the die 112 and the flex circuit cable 108 through the package substrate 116. The flex circuit cable 108 may have a flexible interconnect bus enclosed by an insulating flexible casing material, e.g., rubber or plastic. The flexible interconnect bus may have pairs of signal traces without having a dedicated ground or power trace/plane. In one embodiment, the ground and power transfers supplied to the die 112 may be sent through the board 120, thereby at least facilitating the use of the groundless flex circuit cable 108. The flex circuit cable 108 could also include an end 110 to facilitate the coupling to the package substrate 116.

The die 112 may include an integrated circuit formed in a piece of semiconductor material. Examples of such semiconductor material may include, but are not limited to silicon, silicon on sapphire, silicon germanium, and gallium arsenide. Examples of the die 112 may include, but are not limited to a processor (e.g., a central processing unit, a graphics processor, a digital signal processor, a network processor, etc.), an input/output device, a system on a chip (SOC), and volatile memory. In various embodiments, the semiconductor package 104 may also include more than one die attached to the package substrate 116, for example, in a chipset configuration.

The package substrate 116 may be used for support, to interconnect multiple components, and/or to facilitate electrical connections with other components. The package substrate 116 may be made of one or more dielectric and/or ceramic layers. Electrically conductive paths, including a variety of traces and vias of different lengths, widths, and spacings, may be included in the package substrate 116. These electrically conductive paths may be used to route the various signal, ground, and power paths to and from the die 112. Electrically conductive paths may be coupled to both the flex circuit cable 108 and to a board 120.

The semiconductor package 104 may be connected to the board 120 in order to interconnect multiple components such as, e.g., other semiconductor packages, high-power resistors, mechanical switches, and capacitors, which are not readily placed onto the package substrate 116. The semiconductor package 104 may be mounted directly onto the board 120 by connectors 124, which may be, for example, solder balls or pin/socket connectors. In various embodiments the semiconductor package 104 may include a land grid array (LGA) package, a micro pin grid array (mPGA) package, a pin grid array (PGA), a ball grid array (BGA), and the like. The board 120 may represent, for example, a carrier, a printed circuit board (PCB), a printed circuit card (PCC), a backplane, or a motherboard. Board materials could include, but are not limited to, ceramic (thick-filmed, co-fired, or thin-filmed), plastic, and glass.

As signals travel between the board 120 and the die 112 through the connectors 124 they may experience discontinuities that result in impedance mismatches. These mismatches may cause reflections that could limit the data transfer bit rates that may be reliably transmitted.

Impedance mismatches may also limit the distance that the signals may travel through board traces. Signals may experience deterioration as they travel through the board 120, which may have a relatively high electrical loss tangent compared to the flex circuit cable 108. For example, in one embodiment, the board 120 may be a flame retardant 4-printed circuit board (FR4-PCB), which may have an electrical loss tangent around 0.021-0.025, while the flex circuit cable 108 may include a dielectric made of, for example, polytetrafluoroethylene (PTFE), polyamide, a liquid crystal polymer, and the like. Such a flex circuit cable 108 may have electrical loss tangents less than 0.002, or so, which may allow for signals to travel longer distances through board traces at increased data transfer bit rates as compared to signals traveling through the board 120.

This signal deterioration may increase proportionally with the data transfer bit rates at which the signals are transmitted. Therefore, in one embodiment, higher speed signals may be routed to/from the die 112 through the flex circuit cable 108, while relatively lower speed signals may be routed through the board 120 where they may experience less significant deterioration.

In one embodiment, the end 110 of the flex circuit cable 108 may be electrically coupled to the topside of the package substrate 116 by, for example, a hat bar solder or a gold bump-pad. In this embodiment, the signals transmitted between the flex circuit cable 108 and the die 112 may only have to travel through the package substrate 116 without going through the connectors 124 into the board 120. This embodiment could thereby result in a reduction of parasitic impedance and/or wave reflection back along the signal line due to the discontinuities of the signal path from the die 112 to the board 120. While the electrical coupling may also serve to mechanically couple the end 110 to the package substrate 116, various embodiments may reinforce the mechanical coupling with other connectors, such as one or more pins placed in the corners of the end 110.

FIG. 2 illustrates a cross-sectional view of a flex interconnect bus 200 of the flex circuit cable 108 that may be used to route differential signals to and/or from the die 112, in accordance with an embodiment of the present invention. The flex interconnect bus 200, as shown, may include two signal trace pairs 204 and 208 separated by a flexible packaging material, such as a dielectric material 210 without having a ground trace or plane. The signal trace pairs 204 and 208 may be arranged as a transmitting line and receiving line to allow for the respective transmitting and receiving of differential signals to and from the die 112. Various embodiments may have any number of signal trace pairs.

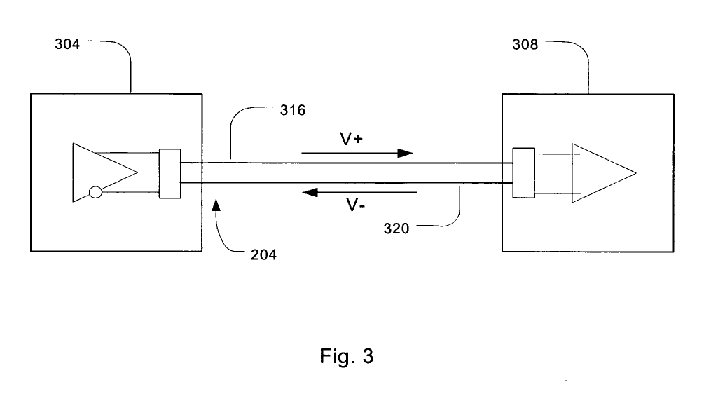

FIG. 3 illustrates the transmitting signal trace pair 204 coupling two semiconductor packages, in accordance with an embodiment of the present invention. In particular this embodiment may include a driver package 304 coupled to transmit differential signals to a receiver package 308 through the signal trace pair 204. Semiconductor packages of various embodiments may include facilities to accommodate both the transmission and reception of differential signals.

In this embodiment, signal traces 316 and 320 may have V+ voltage and a V− voltage, respectfully. The receiver package 308 may be sensitive to a differential signal level on the two traces 316 and 320 and compare the differential signal level to a threshold level to determine a binary state of the transmitted signal. Because the voltages on traces 316 and 320 are referenced to one another, the receiver package 308 does not need a separate reference voltage for the differential signals. The differential signals sent on signal trace pair 204 may be resistant to noise, as any noise present may have similar effect on both traces 316 and 320 and appear as common-mode voltage at the receiver package 308. This arrangement may also enable relatively low voltage applications, as differential signaling may be relatively insensitive to absolute voltage levels compared to single-ended signaling.

Differential signaling, especially in low voltage applications, may provide a number of additional desirable characteristics compared to single-ended signaling including, but not limited to, reduced electromagnetic interference, improvements in switching speeds, and reduction in power consumption. The above characteristics may at least facilitate the use of a groundless flex circuit cable for transmission of differential signals over distances at high data transfer bit rates. An example of differential signaling is low voltage differential signaling (LVDS), which may use, for example, a 500 mV differential signal at 1.2V.

Referring also to FIG. 1, in one embodiment, providing a groundless flex circuit cable 108 may allow for the end 110 to accommodate more signal (as opposed to ground) connections. Additionally, the flex circuit cable 108 may be a single layer, which may facilitate the flex circuit cable 108 maintaining a low-loss characteristic (e.g., having an electrical loss tangent less than 0.01). Not providing grounds for the signals transmitted through the flex circuit cable 108 could also allow for smaller package substrate 116 and/or board 120 dimensions as the amount of electrical pathways may be reduced in each. Such a reduction in dimensions may translate into cost and resource savings for embodiments of the present invention.

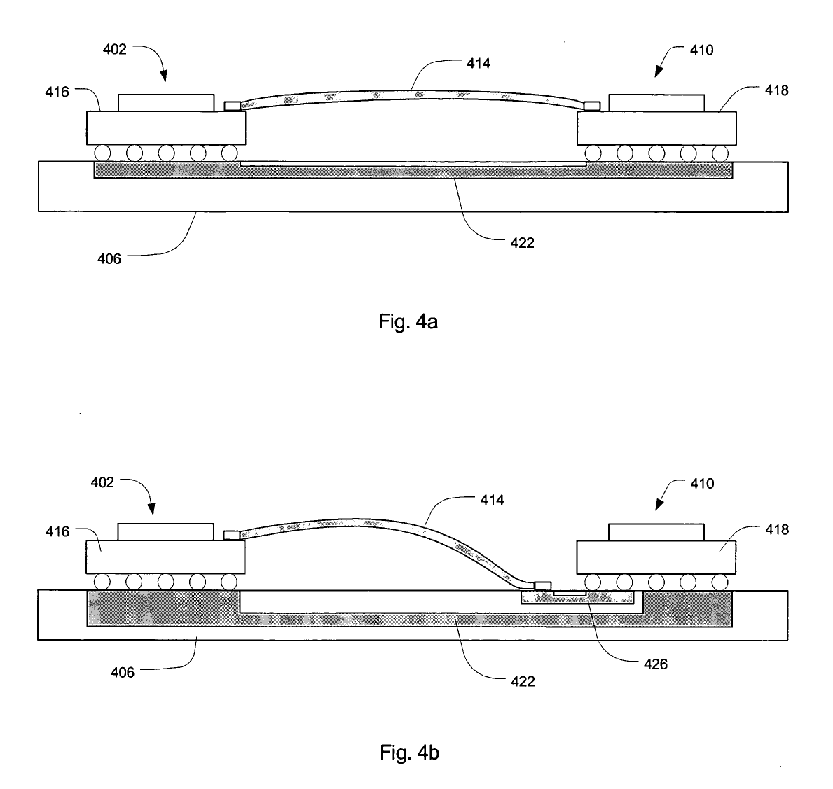

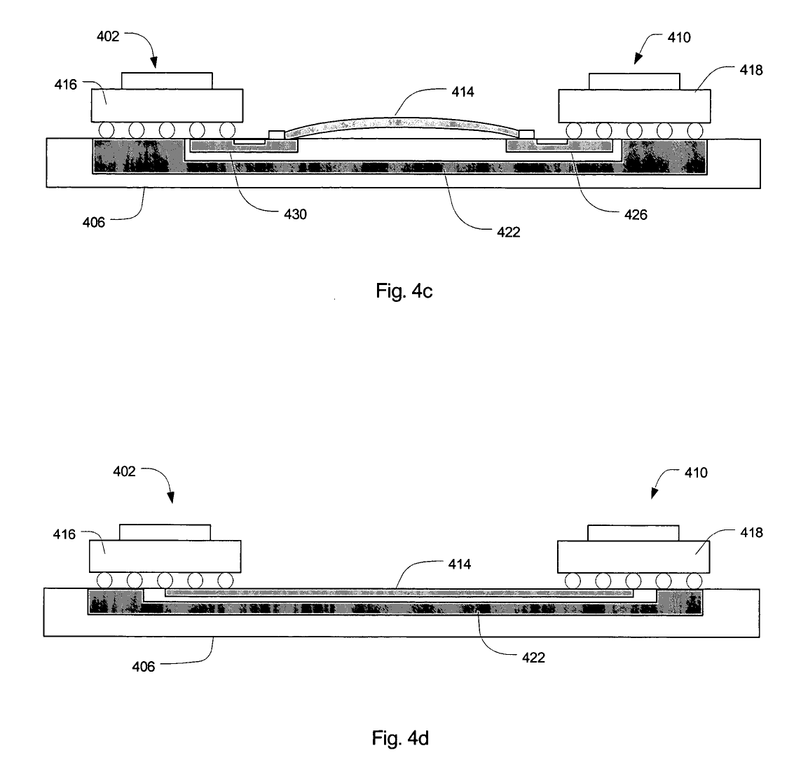

FIG. 4a illustrates a cross-sectional view of semiconductor packages coupled to one another in accordance with an embodiment of the present invention. In particular, this embodiment may include a semiconductor package 402 coupled to a board 406 and electrically coupled to a semiconductor package 410 through a flex circuit cable 414, as shown. In one embodiment the two ends of the flex circuit cable 414 are coupled to the semiconductor packages 402 and 410 through respective package substrates 416 and 418. The semiconductor packages 402 and 410, the board 406, and the flex circuit cable 414 may be similar to like components described with reference to FIGS. 1 and 2.

In one embodiment, differential signals may be routed between the semiconductor packages 402 and 410 through the flex circuit cable 414. In one embodiment, relatively low-speed input/output (I/O) signals may be routed between the semiconductor packages 402 and 410 through signal traces 422 in the board 406, while high-speed I/O signals are routed through the flex circuit cable 414. Having the high-speed I/O signals routed over the flex circuit cable 414, which may have a lower electrical loss tangent than the board 406, may allow for the semiconductor packages 402 and 410 to be further away from one another, without sacrificing signal integrity. In one embodiment, ground and/or power may be respectively provided to the semiconductor packages 402 and 410 from the board 406. In this embodiment, the flex circuit cable 414 may be detached from the board 406, which may provide, among other things, additional space for mounting components on the surface of the board 406 beneath the flex circuit cable 414.

As depicted, both the semiconductor packages 402 and 410 are on the same board 406; however, this may not be the case in other embodiments. That is, various embodiments may include a flex circuit cable coupling semiconductor packages residing on different boards.

FIG. 4b illustrates another embodiment using the flex circuit cable 414 to couple the semiconductor package 402 with the semiconductor package 410. In this embodiment, the first end of the flex circuit cable 414 is coupled to the semiconductor package 402 at the package substrate 416; however, the second end of the flex circuit cable 414 is coupled to the board 406. In this embodiment the board 406 may include signal traces 426 to respectively correspond with the signal traces of the flex circuit cable 414. The board signal traces 426 may be used to route the high-speed differential signals to and from the semiconductor package 410.

In one embodiment, the flex circuit cable 414 may be coupled to the board 406 relatively near the semiconductor package 410 so that significant signal loss does not occur due to the signals traveling through the board 406. The desired proximity between the semiconductor package 410 and the point where the flex circuit cable 414 is coupled to the board 406 may be determined for a particular embodiment.

FIG. 4c illustrates an embodiment using the flex circuit cable 414 to couple the semiconductor package 402 with the semiconductor package 410 through board signal traces. In this embodiment, the flex circuit cable 414 may be coupled to the board 406 at both ends. The board 406, in turn, may have signal traces 426 and 430 corresponding to the signal traces of the flex circuit cable 414 to couple the respective semiconductor packages 410 and 402 to the flex circuit cable 414. Similar to above embodiment, the flex circuit cable 414 may be coupled to the board 406 relatively near the semiconductor packages 402 and 410 so that significant signal loss does not occur due to the signals traveling through the board 406.

FIG. 4d illustrates an embodiment having the flex circuit cable 414 being coupled with the board 406. In this embodiment the differential signals may travel to and/or from the semiconductor packages 402 and 410. The flex circuit cable 414 may be attached to or embedded in the board 406. In an embodiment where the flex circuit cable 414 has a lower loss characteristic, the differential signals may not experience the same degree of loss traveling between the semiconductor packages 402 and 410 as they would if the signal traces were internal to the board 406.

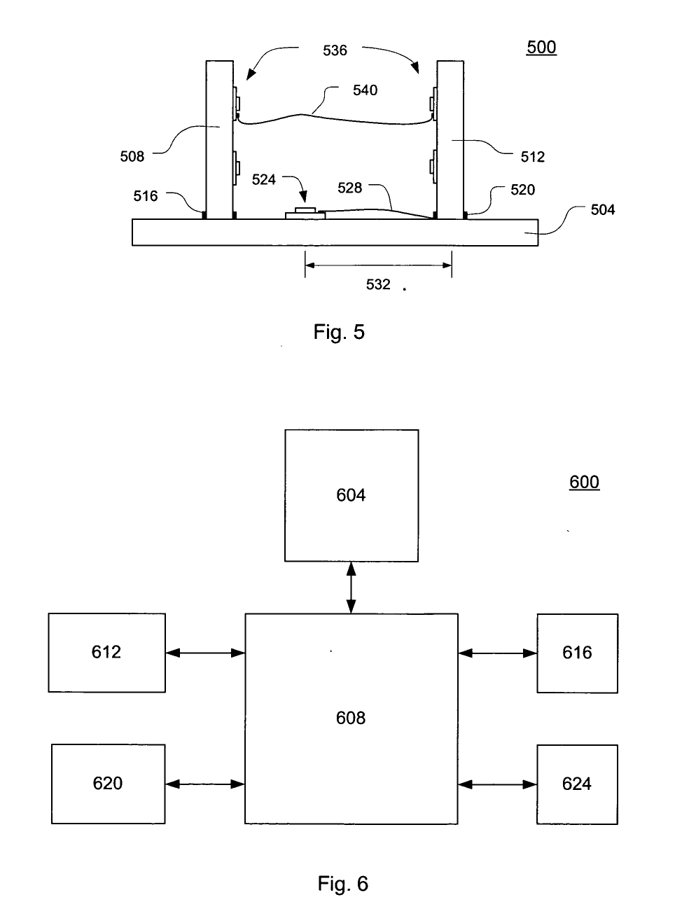

FIG. 5 illustrates a backplane arrangement 500 utilizing flex circuit cables to couple components together, in accordance with an embodiment of the present invention. In this embodiment a backplane 504, which may be a circuit board, may receive cards 508 and 512 in card slots 516 and 520, respectively. Cards 508 and 512 may also be referred to as line cards or blades, and these terms as used herein are intended to be synonymous. In one embodiment, these cards 508 and 512 may also be circuit boards and may be designed to mate with the backplane 504 to provide modular extensibility. In various embodiments, these cards 508 and 512 may provide additional logic, I/O modules, memory, etc., to the backplane arrangement 500. The backplane 504 may be adapted to accommodate any number of cards depending on the scalability of the particular embodiment. The backplane 504 may include a central processing node 524, e.g., a local area network (LAN) controller, to control data traffic to/from the cards 508 and 512.

Conventional backplane arrangements may be geometrically constrained due to limitations on routing high-speed signals through the printed circuit boards over distance, as discussed above. As a result of these limitations, conventional backplane arrangements have limited the distance that the cards can be placed from a central processing node, and therefore the backplane trace length, to about 20 inches or less.

In the embodiment depicted by FIG. 5, the card slot 520 may be coupled to the central processing node 524 through a flex circuit cable 528. In various embodiments, high-speed signals may be routed between the central processing node 524 and the card 512 through the flex circuit cable 528, while low-speed signals may be routed through traces in the backplane 504. In this manner, the distance 532 that the card 512 may be placed from the central processing node 524, and therefore the length of the backplane traces, may be greater than 20 inches if need be.

Each card 508 and 512 may include one or more semiconductor packages 536 to facilitate the particular functionality of the card. In one embodiment, a semiconductor package 536 on card 508 may be coupled to a semiconductor package 536 and card 512 with a flex circuit cable 540. In some embodiments, one or more of the semiconductor packages 536 may be coupled to the central processing node 524 or the backplane 504 with a flex circuit cable.

In various embodiments, either of the flex circuit cables 528 or 540 may be used independently or in combination with other flex circuit cables coupling together various components.

Various embodiments may employ any combination of the above coupling configurations with flex circuit cables as well as others consistent with the scope of this invention.

FIG. 6 shows an example of a system 600 suitable for employing a flex circuit cable in accordance with an embodiment of this invention. In one embodiment a processing node 604 (e.g., one or more central processing units) could be coupled to a hub module 608 that may act as an intermediary between the processing node 604 and the other components. The processing node 604 could include a control unit, an arithmetic logic unit, and memory (e.g., registers, caches, RAM, and ROM) as well as various temporary buffers and other logic. In various embodiments the processing node 604 may be an application specific integrated circuit (ASIC), stacked or multichip modules, a digital signal processor, a blade processor, a network processor, etc.

In one embodiment the hub module 608 may arbitrate data and processing requests between the processing node 604 and a graphics processor 612, memory 616, mass storage device 620, and/or other input/output (I/O) modules 624. The hub module 608 may include, for example, a memory bridge, an I/O bridge, and/or a switch as either integrated or discrete components to facilitate the flow of data and processing requests. In one embodiment, the hub module 608 may include logic to allow for peer-to-peer communication without sending the traffic to the processing node 604. Examples of the memory 616 include but are not limited to static random access memory (SRAM) and dynamic random access memory (DRAM). Examples of the mass storage device 620 include but are not limited to a hard disk drive, a compact disk drive (CD), a digital versatile disk drive (DVD), and so forth. Examples of the I/O modules 624 include but are not limited to a keyboard, cursor control devices, a display, a network interface, and so forth. The network interface may be adapted to couple to networks having a variety of topologies, protocols, and architectures. In various embodiments, one or more of the I/O modules 624 may be coupled to the hub module through a peripheral component interconnect (PCI) slot.

The components of system 600 may be coupled to one another as shown by being disposed on the same or different boards. Examples of the boards may include but are not limited to, line cards, expansion boards, motherboards, and backplanes. In various embodiments, a flex circuit cable, similar to the flex circuit cable described with reference to the above embodiments, may be used to interface with one or more of the components of system 600 using differential signals. In an embodiment, the flex circuit cable may be used to couple the hub module 608 to the graphics processor 612 and/or one or more of the I/O modules 604. In various embodiments, the flex interconnect bus of the flex circuit cable may comprise at least a portion of a peripheral interconnect express (PCI Express) link between components.

In various embodiments, the system 600 may be a wireless mobile phone, a personal digital assistant, a tablet PC, a notebook PC, a set-top box, an audio/video controller, a networking router, a networking switch, a workstation, and a server.

Thus, it can be seen from the above descriptions, a novel approach for a groundless flex circuit cable to facilitate connections with semiconductor packages has been described.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the above embodiments without departing from the scope of the present invention. Those with skill in the art will readily appreciate that the present invention may be implemented in a wide variety of embodiments. This application is intended to cover any adaptations or variations of the embodiments discussed herein. Therefore, it is manifestly intended that this invention be limited only by the claims and the equivalents thereof.

What is claimed is:

1. An apparatus comprising:
a first semiconductor package having a first die; and
a flex circuit cable having a flexible interconnect bus consisting of a plurality of signal traces and a flexible packaging material, to facilitate sending and receiving differential electrical signals from and to the first die.

2. The apparatus of claim 1, wherein the flexible packaging material includes a dielectric material to separate the plurality of signal traces.

3. The apparatus of claim 1, wherein the flex circuit cable includes a first end coupled to the first semiconductor package.

4. The apparatus of claim 3, further comprising:
a second semiconductor package having a second die; and
the flex circuit cable having a second end coupled to the second semiconductor package to facilitate sending and receiving differential electrical signals at a first speed from and to the second die.

5. The apparatus of claim 4, further comprising:
a circuit board, coupled to a first side of the first and second semiconductor packages to provide at least ground and power to the first and second dice, which are respectively coupled to a second side of the first and second semiconductor packages.

6. The apparatus of claim 5, wherein the second end is coupled to the second semiconductor package at the semiconductor package.

7. The apparatus of claim 5, wherein the second end is coupled to the second semiconductor package at the circuit board, and the circuit board further comprises a plurality of signal traces respectively coupled to the plurality of signal traces of the flexible interconnect bus, to facilitate transmitting differential electrical signals from and to the second die.

8. The apparatus of claim 5, wherein the circuit board further comprises a plurality of signal traces to facilitate sending and receiving electrical signals between the first and the second dice at a second speed that is less than the first speed.

9. The apparatus of claim 5, wherein the first end is coupled to the first semiconductor package at the second side.

10. The apparatus of claim 5, wherein the first end is coupled to the first semiconductor package at the first side.

11. The apparatus of claim 10, wherein at least a portion of the flex circuit cable is attached to or embedded in the circuit board.

12. The apparatus of claim 4, further comprising:
a first circuit board, coupled to the first semiconductor package, including a card slot; and
a second circuit board, coupled to the second semiconductor package and coupled to the first circuit board at the card slot.

13. A method comprising:
routing a plurality of differential signals from and to a first die of a first semiconductor package at a first speed through a flex circuit cable having a flexible interconnect bus consisting of a plurality of signal traces and a flexible packaging material; and
providing at least power and ground to the first die from a circuit board coupled to the first semiconductor package.

14. The method of claim 13, further comprising:
routing a plurality of signals from and to the first die at a second speed from the circuit board, the second speed being less than the first speed.

15. The method of claim 14, further comprising:
routing the plurality of differential signals between the first die and a second die of a second semiconductor package through the flex circuit cable.

16. The method of claim 15, wherein the plurality of differential signals are routed between the first and the second die, through a plurality of signal traces in the circuit board respectively coupled to the plurality of signal traces in the flex circuit cable.

17. The method of claim 13, wherein the flex circuit cable is attached to or imbedded in the board.

18. An apparatus comprising:
a first semiconductor package having a first die; and
a flex circuit cable having a flexible interconnect bus consisting of a single layer, a plurality of traces disposed thereon, having a first end, and coupled to the first semiconductor package at the first end, to facilitate sending and receiving differential electrical signals from and to the first die.

19. The apparatus of claim 18, wherein the single layer includes a dielectric between the plurality of traces, the dielectric selected from a group of materials consisting of a polytetrafluorethylene (PTFE), a polyamide, and a liquid crystal polymer.

20. The apparatus of claim 18, further comprising:
a circuit board coupled to the first semiconductor package to provide at least ground and power to the first die.

21. The apparatus of claim 20, wherein the flex circuit cable has a first electrical loss tangent, and the circuit board has a second electrical loss tangent that is greater than the first electrical loss tangent.

22. The apparatus of claim 21, wherein the first electrical loss tangent is less than or equal to about 0.002.

23. The apparatus of claim 20, wherein the flex circuit is coupled to the first semiconductor package at the first end by at least a selected one of a group consisting of a gold bump-pad and a hat bar solder.

24. A method comprising:
routing a plurality of differential signals from and to a first die of a first semiconductor package at a first speed through a flex circuit cable having a flexible interconnect bus consisting of a single layer, having a plurality of traces disposed thereon; and
providing at least power and ground to the first die from a circuit board coupled to the first semiconductor package.

25. The method of claim 24, further comprising:
routing a plurality of signals from and to the first die at a second speed through the circuit board, wherein the first speed is greater than the second speed.

26. The method of claim 25, wherein the flex circuit cable has a first electrical loss tangent, and the circuit board has a second electrical loss tangent that is greater than the first electrical loss tangent.

27. A system comprising:
a processing node;
a hub module, coupled to the processing node to facilitate data transfer and processing requests from and to the processing node; and
a networking interface coupled to the hub module to transfer differential signals from and to the hub module through a first flex circuit cable having a flexible interconnect bus consisting of a plurality of signal traces separated by a dielectric material.

28. The system of claim 27, further comprising:
a graphics processor, coupled to the hub module to transfer differential signals from and to the hub module through a second flex circuit cable.

29. The system of claim 27, wherein the processing node includes a microprocessor.

30. The system of claim 29, wherein the system is a selected one of a group consisting of a server, an audio/video controller, a router, and a switch.
